(19) United States
(12) Patent Application Publication
(10) Pub. No.: US 2006/0218455 A1
(43) Pub. Date: Sep. 28, 2006

(54) Integrated circuit margin stress test system

(75) Inventors: Kevin Robert LeClair, Prior Lake, MN (US); Thomas Robert Wik, Livermore, CA (US); Chuong Tien Le, San Jose, CA (US); Hieu Dinh Nguyen, San Jose, CA (US); Duytan Kiem Tran, Los Gatos, CA (US); Kevin Owen Bligh, Ione, CA (US)

Correspondence Address: TRAN & ASSOCIATES, 6768 MEADOW VISTA CT., SAN JOSE, CA, 95135, US

(73) Assignee: Silicon Design Solution, Inc.

(21) Appl. No.: 11/089,300

(22) Filed: Mar. 23, 2005

(51) Int. Cl. G01R 31/28

(52) U.S. Cl. 714/726

(57) ABSTRACT

Systems and methods are disclosed for testing a synchronous memory system by electrically stressing one or more electrical conditions of the component circuits; providing a Built-In Self-Test (BIST) controller to control the electrical stress during device testing; and providing a test stimuli during testing. In another aspect, the memory system testing includes setting a self-timed control input of the memory system to a predetermined self timed period value; and testing the memory based on the predetermined self timed period value.

### BACKGROUND

Many of today's integrated circuit (IC) designs are a complete system on a chip (SOC) that include a processor core, multiple embedded memories, logic, I/O ports, among others. As ICs are produced with greater levels of circuit density, efficient testing schemes that guarantee very high fault coverage while minimizing test cost and chip area overhead have become essential. However, as the complexity of circuits continues to increase, high-fault coverage of several types of fault models becomes more difficult to achieve with traditional testing paradigms.

Memories are also the most sensitive to manufacturing process defects, making it essential to thoroughly test them in a SOC. There are generally three approaches to testing of embedded memories. One technique is to use automatic test equipment (ATE) that is located external to the circuit under test and that applies test patterns stored in the ATE. External ATE applies a set of fully specified test patterns one by one to a circuit under test in scan mode via scan chains within the circuit. The circuit is then run in normal mode using the test pattern as input, and the test response to the test pattern is stored in the scan chains. With the circuit again in scan mode, the responses are routed to the tester, which compares the response with the fault free reference response. This approach is advantageous because there are a wide variety of test algorithms that can be used and the algorithms can easily be changed in the ATE. However, as the complexity of circuits continues to increase, the ATE approach to testing embedded memories has become increasingly difficult. Another technique for testing of embedded memories is to use an embedded CPU. Using an embedded CPU is advantageous because no additional testing hardware is needed and the test algorithms can be easily modified. However, the CPU does not always have access to all of the memories on the integrated circuit. Additionally, it is difficult to automate the process to program the CPU for generation of the memory test algorithms. Finally, it is very difficult to test the memories that store the memory test program itself. The third approach to testing embedded memories is to use Built-in self-test (BIST) techniques. BIST has become the most popular method for testing embedded memories. To use this method, one or more BIST controllers are inserted within the SOC during the chip's design using a software design tool. The chip is then fabricated with the added BIST controllers. During testing of the fabricated chip, a BIST controller is instructed to supply a series of patterns to the ports of an embedded memory. These patterns, also called test algorithms, typically include, but are not limited to, march-type and checkerboard-type patterns that cause a memory to produce deterministic output data. The output data can be directly compared with reference data from the BIST controller. The comparison generates a signal indicating that the memory passed or failed the test.

FIG. 1 shows an exemplary conventional BIST arrangement. A synchronous memory array 10 is exercised by a BIST controller 20. The BIST controller 20 drives signals on control buses, address buses, and data buses.

U.S. Pat. No. 5,883,843 discloses an integrated circuit with a built-in self-test (BIST) arrangement including a read only memory (ROM) that stores test algorithm instructions. A ROM logic circuit receives an instruction read from the read only memory and produces a group of output signals dependent upon the instruction. A BIST register receives and stores the group of output signals from the logic circuit for controlling self-test of the integrated circuit.

U.S. Pat. No. 6,415,403 discloses a BIST controller that can be used at higher levels of assembly and for commodity memories to perform functional and AC memory tests. A BIST controller comprising a finite state machine is used to step through a test sequence and control a sequence controller. The sequence controller provides data and timing sequences to the embedded memory to provide page mode and non-page mode tests along with a refresh test. The BIST logic is scan tested prior to performing the built in self test and accommodations for normal memory refresh is made throughout the testing. The BIST also accommodates a burn-in test where unique burn-in test sequences can be applied.

U.S. Pat. No. 6,829,728 discloses a full-speed BIST controller for testing embedded synchronous memories. A BIST controller is used to address the memory and provide reference data that is compared to the memory output. Pipeline registers are used to allow the BIST controller to perform reads and/or writes during every clock cycle. In one aspect, the BIST controller includes a reference data circuit that stores or generates data for comparison to the memory output. A pipeline register is positioned before the reference data circuit or between the reference data circuit and compare circuitry. Additional pipeline registers may be positioned between a compare capture circuit and the compare circuitry. The pipeline registers free the BIST controller from having to wait for a read to complete before starting the next read or write. To reduce the number of pipeline registers needed, a negative-edge BIST controller can be used with a positive-edge memory or vice versa.

Embedded memory arrays are the densest components within a SOC, accounting for a significant percentage of the chip area. Embedded synchronous memories are typically designed with a specialized internal timing circuit that controls when the memory is accessed and when the memory is precharged. The internal timing circuit creates a self-time period (STP) that ultimately controls the amount of bit line separation that is created before the sensing operation. During the design phase, care must be taken to ensure the STP provides sufficient bit line separation for all process, voltage, and temperature variations, and across all configuration space of different memory configurations. Once the setting is established, the STP is fixed and not available for fine-tuning. At factory, and out in the field, the memories are usually tested with a BIST (Built In Self Test) engine, and the memories will be tested with the STP established during the design phase.

BIST engines are used to validate the memory at manufacturing, and also out in the field during power up. Since the STP period is fixed, the BIST will test the memory only at the setting defined during the design process. Defects in the processing of the memory can result in bit cells that are weaker than others and hence deliver less bit line separation than expected. Other processing defects could cause bit cell to degrade over time, again causing inadequate bit line separation. These degradations alter the required STP period for the affected bit cells and affect memory reliability.

The likelihood of encountering weak bits that are very close to the failure point is increased significantly in modern deep-submicron technologies. This is due primarily to two effects. The first is the continuing exponential increase in the number of memory bits on each chip. The second is the tendency for the variability of important electrical parameters to increase on a percentage basis with each subsequent technology generation. The effects of threshold voltage variation, for example, are much greater for 90-nanometer technology than for earlier generations of technology. These effects combine to increase the statistical probability that a memory bit cell will be just strong enough to pass under test conditions but fail in field use or perhaps fail in field use after aging effects have further degraded the operating margin of the bit cell.

### SUMMARY

Systems and methods are disclosed for testing a synchronous memory system having a self-timed control input by setting the self-timed control input to a predetermined self timed period value; and testing the synchronous memory based on the predetermined self timed period value.

Advantages of the system may include one or more of the following. The system enhances reliability by testing for variations in the STP timing. By reducing, increasing, or otherwise adjusting the STP, some defects may be detected for extended testing. The memory can be tested at its preferred self-time timeout setting, and subsequently at a shorter timeout setting, to identify weak memory cells, or to find out how much margin the memory has at a given process, voltage, or temperature. The memory can also be tested at a longer self-time interval to insure that there is adequate margin on the access time for the memory. These tests, at faster and/or slower time-out intervals, can be used as needed in order to achieve the test escape rates that are needed. If there is a substantial amount of access time margin, for example, it may not be necessary to implement the extra test with longer self-time interval. These additional margin tests would be performed only in the factory test for screening of marginal parts. Field use and field testing would be performed only at the nominal fixed STP setting.

Since the STP period is adjustable during test, the BIST will test the memory more effectively. The BIST engine can test for defects in the processing of the memory that can result in bit cells that are weaker than others and hence deliver less bit line separation than expected. This enhanced capability to screen out bit cells with very little signal margin eliminates bits that might fail under slightly different use conditions than were applied during testing. It also insures that the worst-case bit cells have a minimum signal buffer that reduces the likelihood that degradation of the signal over time will result in life failures.

The system can also be used to program a memory to be less aggressive, or more aggressive, depending on the application. In some cases, where the memory is in the critical path, the STP may be decreased to accommodate a faster access time. Typically the STP is designed to cover worse case everything, i.e. process, temperature, voltage, coupling, noise, etc. Often the memory is over designed, and for a given process run, may be capable of running faster than what it was designed for. By modifying the BIST algorithm, and interfacing to the self-time circuitry of the memory, the memory performance can be improved by decreasing the STP. In other cases, the memory is not in the critical path of the design, and as such, the design could tolerate a slower, and more robust, memory. By increasing the STP, the memory would be more robust and immune from degradation over time, or noise from other parts of the design. This could lead to fewer returned parts and better FIT rates.

The margin test system can also be used to test for increased robustness against write failures of the worst-case bit on an integrated circuit. Write failures of SRAM cells, for example, can occur when the voltage level impressed on the bit line during the write operation is insufficient to flip the worst-case bit cell. The addition of a voltage stress that purposely degrades the voltage level impressed on the bit line during the write operation performed during the margin test makes it possible to screen out bits that are too close to the point of failure to allow reliable operation.

The margin test system can also be used to screen out parts that have a timing transition edge that is too close to the operating limit to allow reliable operation. Timing delays can be adjusted during margin test under the control of the test controller in a manner to provide incremental timing stress on the unreliable circuit thereby causing it to fail during test rather than in the field.

The margin test system can be used to apply any electrical or timing stress on potentially weak or unreliable circuit elements to screen them out during test so they do not fail in the field.

### BRIEF DESCRIPTION OF THE FIGURES

This invention will be described with reference to the accompanying drawings, wherein:

FIG. 1 shows an exemplary conventional embedded test system with an on-chip memory BIST test controller.

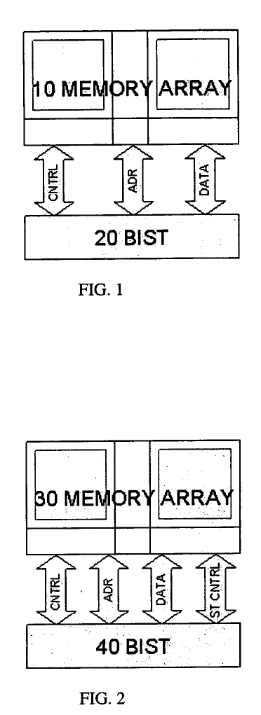

FIG. 2 shows an exemplary embedded system with Stress Test (ST) control added to the on-chip test controller.

FIG. 3 shows more details on the exemplary embedded system of FIG. 2 in which the Stress Test is accomplished by varying the Self-Time-Period defined by the Reference Column in a synchronous SRAM.

FIG. 4 shows an exemplary process for testing the system of FIG. 3.

FIGS. 5A-5B show exemplary timing margin test circuits that enable variation of timings by adjusting rise and fall times in a timing chain under the control of the Timing Margin Test signals, TMT and TMTN, while FIG. 5C shows one embodiment of a write driver circuit for performing write margin testing.

### DESCRIPTION

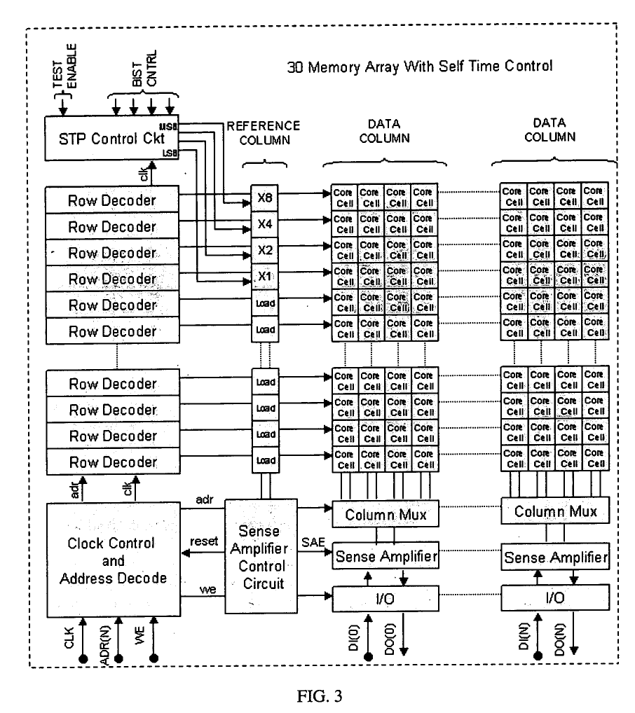

FIG. 2 shows an exemplary embodiment of a synchronous memory system with Stress Test control. In this system, a synchronous memory array 30 is controlled by a BIST controller 40. The array 30 has control bus input, address bus input, data bus input/output, and self-time control bus input for Stress Test control. The BIST controller 40 drives the memory array 30 with corresponding control bus output, address bus output, data bus input/output, and self-time control bus output. The array 30 is designed to operate as a synchronous random access memory during normal operation. Alternatively the built-in self-test arrangement operates in a distinctive self-test mode at times while the device is not operating in the normal mode. The built-in self-test arrangement is designed such that all the test signals are generated internally to a device, and the arrangement only takes a simple setup to get the device into a self-test mode to perform a self test. With the simple setup up, the built-in self-test arrangement performs a memory self-test in a cost-effective procedure. The arrangement also allows many devices to be tested in parallel without being limited by tester resources.

The BIST controller 40 is shown generically and there are a wide variety of forms the BIST controller can take. For example, the registers and circuitry shown within BIST controller 40 may be replaced with combinatorial logic that is controlled by the finite state machine. Such combinatorial logic can be used in conjunction with other internal signals within the BIST controller to produce the desired output signals, such as address, data, and control lines. There are many variables that can affect the internal signals to the combinatorial logic, such as the current data pattern being used and the address of memory currently being tested. The particular structure of the BIST controller is not of importance.

Normal mode operation and self-test mode operation are two separate and distinct operations of the system. Those two modes occur alternatively. Thus while the system operates in its normal mode it is not able to inadvertently go into its self-test mode. Also while it is in its active self-test mode, it cannot inadvertently go into its normal mode. These are conditions that are imposed upon the operation of the system by the BIST controller 40. In one embodiment, self-test mode is entered only upon power up of the memory device. Special signal conditions are applied at that time to put the device into the self-test mode.

The BIST controller controls the interface to the memory. Signals from the design will pass through the BIST controller, or a memory collar associated with the memory. By adding control signals between the BIST controller and the memory, the STP can be altered during the BIST function. With the additional control signals, and interface to the memory self-time control circuit, the BIST controller hardware and algorithm can test the memory with one STP at the preferred setting, and subsequently with more aggressive STP setting and more relaxed STP settings, such that marginal bit cells, memory circuits, and processing defects can be detected. In this manner the BIST controller hardware can apply the Stress Test to test for adequate margin during a special sequence applied during the test mode.

The testing system for production integrated circuits can include a circuit to stress the electrical conditions of component circuits contained in an IC in situ with an interface to an enhanced Built-In Self-Test (BIST) controller or other enhanced test controller having the capability to control the electrical stress during test of the device in response to the external test stimuli provided by the external tester while leaving the IC in the normal unstressed mode during normal field-use operation. The component circuits can be memory instances, where the memory instances are subjected to stressed electrical conditions that reduce memory core cell read and/or write margins, sense amplifier margins, or other critical timing or sensing margins. The memory instances can be embedded memories for an SOC (System-On-a-Chip) integrated circuit containing multiple memory instances together with other component circuits. The embedded memory instances can be electrically stressed by reducing the time allowed for read signal development before the sense amplifier is latched thereby making the cells in the memory array more susceptible to failure during the margin test mode. The time allowed for read signal development can be reduced by changing the Self-Time Period (STP) of the sense amplifier and word line timing circuits of a memory instance generated from a memory compiler.

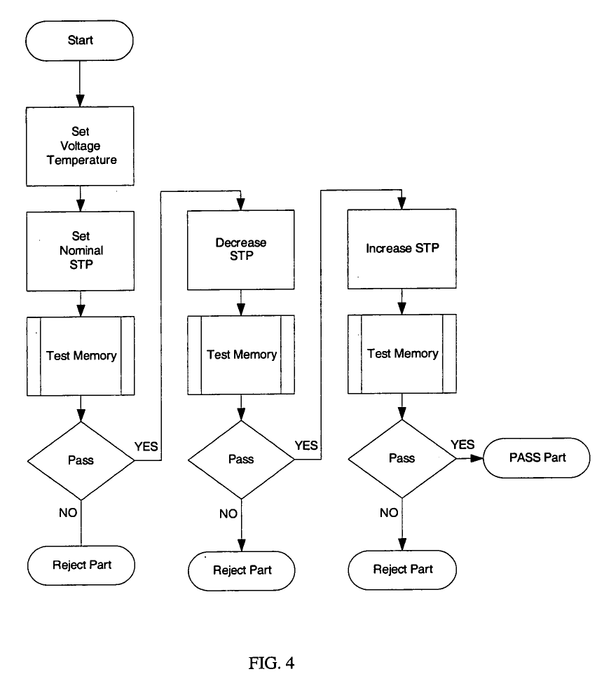

A more detailed circuit of the memory array 30 with the self-timed control circuit within the memory is illustrated in FIG. 3. During normal memory operation, the test enable control is held low. The BIST control inputs are disabled and the drivers for the STP control signals are set to a predetermined state. A memory cycle is initiated by the clock. This starts a memory access cycle.

The internal clock propagates through the address decoder and selects the desired row decoder based on the decoded address. The internal clock will also drive the STP control circuit. The STP control circuit will then drive the appropriate number of reference column core cells, at about the same time as the selected row decoder drives the selected word line. The reference bit line will discharge at a rate proportional to the number of reference core cells, while at the same time the data bit lines will discharge at a rate provided by the memory core cell. Given the linear discharge of the core cell, and the replication of the reference bit lines from the data bit lines, the two will discharge at a rate proportional to the number of core cells driven by the STP control circuit. For example, if there are eight reference core cells selected, the reference bit line will discharge eight times faster than the memory bit line.

The sense amplifier control circuit will generate a clock reset and sense amplifier enable when the reference bit line discharges to the required voltage level. At this time, the data bit lines will be discharged to their desired voltage differential. The sense amplifier will trigger, and the data will be captured.

If there are more reference core cells driving the reference bit line, the reference bit lines will discharge faster and the data bit line differential will be less than preferred when the sense amplifier triggers. However, if there is sufficient margin in the sense amplifier design, the correct data will be captured. And the correct data will be read from the memory even faster than it normally would.

With fewer reference core cells driving the reference bit lines, the reference bit lines will discharge slower, and the data bit line differential will be more than preferred when the sense amplifier triggers. In this case, the sense amplifier will likely capture the correct data, but the bit lines will have discharged more than desired causing more power drain, and the output data will be read from the memory slower than it normally would.

If a weak core cell exists in the array, it will not be able to achieve the desired bit line differential when accessed. However, since significant margin is built into the sense amplifier design, it is possible that the weaker core cell may still be adequate to provide enough bit line differential such that the sense amplifier will read the correct data under normal test conditions. By decreasing the STP slightly, the sense amplifier can be forced to trigger sooner than preferred, and along with the defective core cell, may cause a read error. It would be expected that a slight decrease or increase in the STP timing would not cause typical bit cells to fail given the margin built into the design.

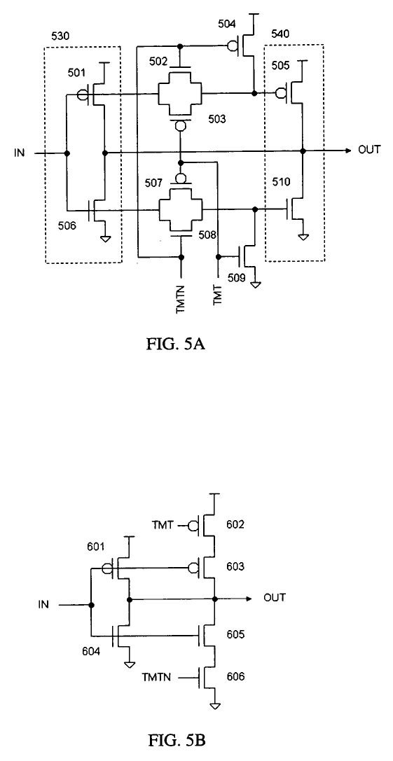

In order to detect the defective core cells or other parts of the memory that are marginal, the BIST controller needs to be able to vary the STP width. With modifications to the BIST controller and the memory, as illustrated in FIG. 4, the STP width can be varied as needed by the BIST algorithm.

FIG. 4 shows an exemplary flow chart executed by the STP control circuit of FIG. 3 for testing the synchronous memory using the variable pulsed-time control. As illustrated in the flowchart, the first sequence is the normal test with the established STP. If the test passes, the test will continue with adjusted STP settings. If the test fails, the part is rejected. During the second sequence, the STP is decreased by the BIST controller and the test is repeated. In this situation, weaker core cells may not being able to provide sufficient bit line separation. If this happens, the sense amplifier would likely read the wrong data, and the test would fail. Again, the part is rejected. If the test passes, the part will be tested with the third sequence. During the third sequence, the STP is increased by the BIST controller. In this case, the bit line separate and access time of the memory is increased. Testing of the memory under these conditions expose some defects associated with a wider bit line separation, including defects associated with increased bit line coupling due to increased dv/dt of the bit lines, sense amplifier coupling due to harder switching, etc. Also, depending on the clocking of the BIST controller observation registers relative to the clocking of the data registers that the memory would normally be interfacing with, this extended STP could reveal inadequate read access margin for the memory. In any case, if the test fails the third sequence, the part is again rejected. Only after the part passes all three sequences will the part be passed. The result will be a more robust memory.

In one embodiment, in addition to the normal test sequence, additional sequences are added, each with new STP setting. Only after the memory passes the original test sequence, and subsequent test sequences as defined by the test algorithm, will the memory be given a passed status.

In another embodiment, a test sequence tests the memory with the variable self time pulse control. The test sequences performed on each cell of the embedded SRAM can include the following: Ra read; Wa write; RaWa′ read contents of cell, complement and immediately write back the complement; and RaWa′Ra′ read contents of cell, complement and immediately write back the complement, and read back the complement from the cell. The BIST controller can also execute a random data pattern memory test, a random address test, and additional tests. These tests include a marching test where patterns are marched across the memory array. This test is similar to a true walk bit test and is able to detect address faults, subset faults, transition faults, coupling faults and late coupling faults. Another test is a walking zero and a walking one pattern across a given test range in blocks of given subsizes.

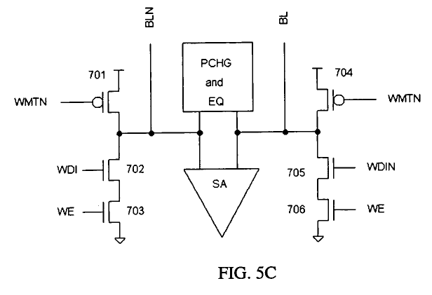

FIGS. 5A-5B shows exemplary circuits that control the timing of output transitions so the timing interval can be set to two or more values under the control of the test algorithm. One of the timing values is set to the nominal timing to be used when the memory is operating in the field. This is the optimized timing interval determined for optimal operation during the design process. The other timing interval(s) is (are) selected to stress the circuit operation by an appropriate amount to check for adequate operating timing margin under all operating conditions and accounting for effects of device aging. The timing interval that is operative in the memory is selectable under the control of the test algorithm. The technique can be applied to one or more critical timing nodes as needed to insure adequate timing margin on all necessary timing transitions.

In principle any circuit technique that modifies the timing of the transition on a critical output node can be used and any tester could be used to enable the special test mode with timing margin including a BIST controller, a scan path, or an external ATE tester. However, the added circuitry should have minimal impact on normal operation of the memory in the user application.

FIGS. 5A-5B show exemplary margin test circuits that enable variations in timing during a margin test mode under the control of the test controller. FIGS. 5A-5B show exemplary margin test circuits that enable the effective size of an inverter in a timing chain to be varied by the test controller. Making the effective size of the inverter larger speeds up the signal transition path. Making the effective size of the inverter smaller slows down the signal transition path.

In FIG. 5A the pull-up transistor is split into two transistors, 501 and 505, and the pull-down transistor is split into two transistors, 506 and 510. Transistors 501 and 506 comprise one inverter, 530, and transistors 505 and 510 comprise a second inverter, 540, connected in parallel with the first inverter. The gates of the transistors comprising the first inverter, 530, would be driven by the normal input, IN. The gates of the transistors comprising the second inverter, 540, each would be connected to the normal input, IN, through separate bi-lateral transmission gates comprised of transistors 502 and 503 for the gate of the p-channel transistor, 505, and comprised of transistors 507 and 508 for the gate of the n-channel transistor, 510. The bi-lateral transmission gates are turned on and off under the control of the test controller. When TMT is high and TMTN is low, the transmission gates are turned off. When TMT is low and TMTN is high, the transmission gates are turned on. Transistor 504 is turned on to pull the gate of transistor 505 high when the transmission gate is turned off by applying a low signal on TMTN. Transistor 509 is turned on to pull the gate of transistor 510 low when the transmission gate is turned off by applying a high signal on TMT. This insures that transistors 505 and 510 are actively turned off when the transmission gates are turned off. In this manner the test controller can speed up the signal transmission path by turning on the transmission gates or slow down the transition by turning off the transmission gates simply by controlling the logic state of the signals TMT and TMTN.

In normal field use the bi-lateral transmission gate would be turned on and the second inverter, 540, would work in parallel with the first inverter, 530, to speed up the output transition. The test controller would apply a low signal level on TMT and a high signal level on TMTN. During the margin test mode the bi-lateral transmission gate would be turned off. The test controller would apply a high signal level on TMT and a low signal level on TMTN. This would slow down the transition for the margin test.

If it were desired to speed up a transition to stress the circuit to check for adequate margin, the normal mode would only activate the first inverter and the margin mode would activate both inverters. The test controller would apply a high level to TMT and a low level to TMTN for the normal use mode. The test controller would apply a low level to TMT and a high level to TMTN for the margin stress mode.

The operation of the circuit of FIG. 5B is similar, except that the second parallel inverter stage comprised of transistors 603 and 605 is turned off by shutting off the source current path by applying a low signal level on TMT on the gate of transistor 606 and shutting off the drain path by applying a high signal level on TMTN on the gate of transistor 602. The test controller applies a low signal level on TMT and a high signal level on TMTN to activate the second parallel inverter and thereby increase the effective size of the first inverter comprised of transistors 601 and 604.

The test controller can vary the timing of transitions propagating through these inverter stages by setting the voltage on the control signals, TMT and TMTN. If TMT is set to a high signal level and TMTN is set to a low signal level, the second inverter will be turned off and the transition will be slowed down. If the control signals are set to the opposite states, the transition will be speeded up. Either of these states may correspond to the optimized transition time determined for the design. The test controller can perform the timing margin stress test by setting the control signals to the opposite state from that used in normal operation. The test controller is designed so the test control signals, TMT and TMTN, are always set to the normal mode for field-use operation. These control signals are set to the opposite state from the normal mode in order to apply the timing stress. This is only done during the margin stress test mode.

The exemplary circuits of FIGS. 5A-5B provide a means for controlling the propagation delay through an inverter stage. It is evident to those skilled in the art that other circuit means can be employed to alter the propagation delay through timing circuits including, for example, varying the capacitance load on nodes in the critical path. The essence of this invention is to alter the timing of circuits in a manner that can be varied under the control of a test controller by affecting the state of logical control signals. This enables timing margin stress testing in situ when the integrated circuit is undergoing production pass-fail testing or failure analysis.

FIG. 5C shows one embodiment of a write driver circuit adapted for margin testing of the write level applied to the bit cell. Additional PMOS devices 701 and 704 both having input, WMTN, have been added to control the bit line voltage during write margin stress testing. In normal operation the write driver circuit pulls either the true bit line, BL, or the complement bit line, BLN, low through the series N-channel transistors, 702 and 703 or 705 and 706. Transistor 702 is turned on by applying a high signal level on input, WDI, in order to pull BLN low in order to write “true” data. Transistor, 705, is turned on by applying a high signal level on input, WDIN, in order to pull BL low in order to write “complement” data. Transistors, 703 and 706, are controlled by the Write Enable signal, WE, and are used to select the columns of bits that will be written.

The write margin mode is achieved by turning on P-channel transistors, 701 and 704, during the write operation by applying a low level to the Write Margin Test control signal, WMTN. The P-channel transistors fight the N-channel transistors by providing positive supply current to the N-channel transistors, thereby increasing the voltage level on the written bit line. This makes flipping of the bit cell to the opposite data state more difficult. This achieves the purpose of insuring that the written bit cell has some incremental write margin buffer against a failure to flip the cell in a normal write operation. The amount of write margin buffer against failure can be adjusted by changing the size of the P-channel transistors, 600 and 602—larger transistors increase the write margin and smaller transistors decrease the write margin.

The system discussed above for testing an integrated circuit device having component circuits therein includes a stress circuit to vary one or more electrical conditions of the component circuits; and an on-chip test controller coupled to the stress circuit to control an electrical stress during device testing. An external tester communicates with the on-chip test controller to provide the electrical stress and to provide test stimuli during testing. The external tester would be disconnected and would leave the integrated circuit device in an unstressed mode during field operation.

In one embodiment, the stress circuitry includes added circuitry that controls the change in circuit operation in order to reduce the margin for failure-free circuit operation. The change in circuit operation could be a change in timing, a change in voltage level, a change in current, a change in effective impedance, etc.

In the case of FIG. 3, the stress to be applied is a timing stress that affects the signal level developed on the bit lines in the memory array. The stress circuitry in this case is comprised of the groups of reference cells on the reference bit line together with the control signals that determine whether or not each group of reference cells is turned on during the array access. The number of reference cells turned on can be varied from one to fifteen under the control of the four STP control signals. As the number of reference cells is increased, the time allowed for developing signal on the bit lines in the array is decreased and weak cells are more likely to fail. In this case the unstressed mode is defined as the setting of the four control lines that is specified by the designer as the optimum number for that particular configuration (number of words and number of bits) of the compiled memory. This is the number of active reference cells that was used for simulating the timing specifications for that particular configuration. The memory is stressed during margin stress testing by increasing the number of reference cells during margin test to check for adequate read signal margin of all cells. The memory can also be stressed by decreasing the number of reference cells during margin test to check for adequate access time margin (during the test mode). Access time margin during the test mode would need to be correlated with access time margin requirements during actual field-use operation.

In the case of FIG. 5A, the stress to be applied is a timing stress. In the embodiment, the second inverter and the control gates are added to enable speeding up the transitions under the control of the Timing Margin Test signals, TMT and TMTN. The unstressed mode is defined as the state in which the bi-lateral transmission gates are turned off. This means that the input TMT is high and TMTN is low. In this case only the inverter 502 is operating to drive the transition on the output node. In the design process inverter 502 is sized to provide the optimum timing for normal circuit operation. The devices in the stress circuit are added to make it possible to test the effects of making this timing slightly faster.

In another embodiment, the same circuitry slows down a transition from the optimum value determined for the design. In this case the optimum design includes both inverters 530 and 540. Now the stress circuit is comprised of the two bi-lateral transmission gates and the keeper p-channel transistor and the keeper n-channel transistor. The unstressed mode is defined as the state in which the bi-lateral transmission gates are turned on. This means that the input TMT is low and TMTN is high. This connects both of the inverters to the output and provides the faster transition as called for by the optimum design. The margin test is performed by turning off the bi-lateral transmission gates by applying a logic high level on TMT and a logic low level on TMTN. In this case the devices in the stress circuit are added to make it possible to test the effects of making this timing slightly slower.

In FIG. 5B the stress circuit includes the four transistors on the right-hand side of the schematic for the case in which the normal mode is the slower transition. The stress circuit is comprised of just the two transistors connected to TMT and TMTN for the case in which the normal mode is the faster transition. In this case the two added transistors make it possible to remove the second parallel inverter stage from the timing path.

In the case of FIG. 5C the stress to be applied is a voltage level stress. Raising the lowest voltage that the write driver circuit can impress on the bit lines makes the write operation more likely to fail. In FIG. 5C the stress circuit is comprised of the two p-channel transistors added to the outputs of the write driver circuit. These two transistors are turned on to raise slightly the voltage on the output node of the write driver circuit during the write margin test. This makes it more difficult to flip the memory bit cell during a write operation to insure that all bits have adequate write margin. The unstressed mode is defined as the state in which these two p-channel transistors are turned off so the write driver circuit can pull the low-written bit line as low as possible.

This technique for testing read signal margin and access time margin makes use of the same circuitry used in the compiler to set the Self-Time Period properly for each memory configuration. The correct number of reference cells to be turned on for optimum discharge rate of the reference bit line changes as the number of rows and columns of memory cells in the array is changed. The margin stress is applied by varying the number of reference cells turned on above or below the correct number specified for each memory configuration.

It is to be understood that various terms employed in the description herein are interchangeable. Accordingly, the above description of the invention is illustrative and not limiting. Further modifications will be apparent to one of ordinary skill in the art in light of this disclosure. For example, the same principles and the same considerations for testing memory cells apply for other circuits on integrated circuits. Analogous test techniques similar to the disclosed memory bit cell margin testing can be applied to other circuits used in modern integrated circuits. The above system enables testing that can screen out memory bits and other circuits that are marginal and are likely to fail in system use. This could occur early in the useful life of the part as a result of different conditions from those applied during test or it could occur later in the useful life of the part as a result of device aging effects that further reduce the margin for the affected weak circuits.

The invention has been described in terms of specific examples which are illustrative only and are not to be construed as limiting. For example, although the buffer memory is described as high speed static random access memory (SRAM), the memory can be any suitable memory, including DRAM, EEPROMs, flash, and ferro-electric elements, for example. The invention may be implemented in digital electronic circuitry or in computer hardware, firmware, software, or in combinations of them.

Apparatus of the invention may be implemented in a computer program product tangibly embodied in a machine-readable storage device for execution by a computer processor; and method steps of the invention may be performed by a computer processor executing a program to perform functions of the invention by operating on input data and generating output. Suitable processors include, by way of example, both general and special purpose microprocessors. Storage devices suitable for tangibly embodying computer program instructions include all forms of non-volatile memory including, but not limited to: semiconductor memory devices such as EPROM, EEPROM, and flash devices; magnetic disks (fixed, floppy, and removable); other magnetic media such as tape; optical media such as CD-ROM disks; and magneto-optic devices. Any of the foregoing may be supplemented by, or incorporated in, specially-designed application-specific integrated circuits (ASICs) or suitably programmed field programmable gate arrays (FPGAs).

Examples have been provided for affecting the read margins and write margins of SRAM memory arrays and for affecting a generic timing margin by means of controlling the rise and fall times of inverters in a signal timing path. The margin testing system described here can be applied more generally to any timing interval, voltage level, current level, or mismatch of any electrical parameters such as resistance, capacitance, inductance, threshold voltage, transconductance, etc. The essential features are a circuit means to effect the electrical stress under the control of a test controller by means of a simple logic interface to the stress circuit. This is combined with an external tester and test flow which enables the integrated circuit to be tested under the stress condition to insure the needed margin buffer. The circuits and test flow are designed to insure that the stress condition is removed for normal field-use operation.

While the preferred forms of the invention have been shown in the drawings and described herein, the invention should not be construed as limited to the specific forms shown and described since variations of the preferred forms will be apparent to those skilled in the art. Thus the scope of the invention is defined by the following claims and their equivalents.

What is claimed is:

1. A system for testing an integrated circuit device having component circuits therein, comprising:
a stress circuit to vary one or more electrical conditions of the component circuits;
an on-chip test controller coupled to the stress circuit to control an electrical stress during device testing; and
an external tester coupled to the on-chip test controller to provide the electrical stress and to provide test stimuli during testing, the external tester leaving the integrated circuit device in an unstressed mode during field operation.

2. The system of claim 1, wherein the on-chip test controller consists of a Built-In Self-Test (BIST) controller or a scan chain.

3. The system of claim 1, wherein the electrical stress reduces the timing margin or the sensing margin of the component circuits.

4. The system of claim 1, wherein the component circuits comprise one or more memory instances.

5. The system of claim 4, wherein the memory instances are subjected to stressed electrical conditions that reduce at least one of: a memory cell's read margin, a memory cell's write margin, or a sense amplifier's sensing margin.

6. The system of claim 4, wherein the memory arrays comprise embedded memories contained in an SOC (System-On-a-Chip) integrated circuit.

7. The system of claim 4, comprising a sense amplifier, wherein the embedded memory arrays are electrically stressed by reducing time allowed for read signal development before the sense amplifier is latched to make the cells in the memory arrays more susceptible to failure during the margin test mode.

8. The system of claim 4, wherein time allocated for a read signal development is reduced by changing a Self-Time Period (STP) of the sense amplifier and word line timing circuits of a memory instance generated from a memory compiler.

9. A memory system, comprising:
a synchronous memory array having self-timed period (STP) control input; and
a test controller coupled to the self-timed control input of the synchronous memory array to vary the memory's self-time period during testing.

10. The memory system of claim 9, wherein the test controller comprises:
means for setting the self-timed control input to a predetermined self timed period value; and
means for testing the synchronous memory based on the predetermined self timed period value.

11. The memory system of claim 9, comprising means for varying the self timed period value.

12. The memory system of claim 9, comprising
means for: setting the self-timed control input to a nominal self timed period value; and
means for testing the synchronous memory.

13. The memory system of claim 12, comprising means for
means for increasing the self-timed control input from the nominal self timed period value; and
means for testing the synchronous memory.

14. The memory system of claim 13, comprising means for:
means for decreasing the self-timed control input from the nominal self-timed period value; and
means for testing the synchronous memory.

15. The memory system of claim 9, comprising an STP control circuit coupled to the STP control signals.

16. The memory system of claim 15, comprising reference columns coupled to the STP control circuit.

17. The memory system of claim 9, comprising a row decoder coupled to the STP control circuit.

18. The memory system of claim 9, comprising reference columns coupled to the STP control circuit.

19. The memory system of claim 9, wherein the test controller comprises one of: an external ATE tester, a built-in-self-test (BIST) controller.

20. A method for testing a synchronous memory system having a self-timed control input, comprising:
a. setting the self-timed control input to a predetermined self timed period value; and
b. testing the synchronous memory based on the predetermined self timed period value.

21. The method of claim 20, comprising varying the self timed period value.

22. The method of claim 20, comprising
setting the self-timed control input to a nominal self timed period value; and
testing the synchronous memory.

23. The method of claim 20, comprising:
setting the self-timed control input to an increased self timed period value; and
testing the synchronous memory.

24. The method of claim 20, comprising:
setting the self-timed control input to a decreased self timed period value; and
testing the synchronous memory.

25. The method of claim 20, comprising disabling the self-timed control input during operation.

26. The method of claim 20, comprising enabling the self-timed control input during operation.

27. The method of claim 20, comprising testing using one of: an external ATE, and a built-in-self-test (BIST) controller.

28. A method for testing embedded synchronous memory in an integrated circuit, the method comprising:
generating an expected data value;
setting a self timed period value for the synchronous memory;
delivering test data, separate from control data and address data, to the memory;
reading an actual data value from the memory corresponding to the delivered test data; and
comparing the actual data value to the expected data value.

29. A method for testing an integrated circuit device having component circuits therein, comprising:
electrically stressing one or more electrical conditions of the component circuits;
providing a Built-In Self-Test (BIST) controller to control the electrical stress during device testing; and
providing a test stimuli during testing.

30. The method of claim 29, wherein the component circuits comprise one or more memory arrays.

31. The method of claim 30, comprising subjecting the memory array to stressed electrical conditions that reduce at least one of: a memory cell read/write margin and a sense amplifier margin.
